(19) United States
(12) Patent Application Publication
(10) Pub. No.: US 2010/0201609 A1
(43) Pub. Date: Aug. 12, 2010

(54) ORGANIC LIGHT EMITTING DIODE DISPLAY DEVICE

(75) Inventor: Eun-Ah KIM, Yongin-city (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Yongin-city (KR)

(21) Appl. No.: 12/697,529

(22) Filed: Feb. 1, 2010

(30) Foreign Application Priority Data
Feb. 6, 2009 (KR) 10-2009-0009730

(51) Int. Cl. G09G 3/30; H01J 1/62

(52) U.S. Cl. 345/76; 313/504

(57) ABSTRACT

An organic light emitting diode (OLED) display device including a first substrate, OLEDs disposed on the first substrate, a second substrate facing the first substrate, and reflective layers disposed on the encapsulation substrate. The reflective layers are offset with respect to the OLEDs, so that the OLED display device can be used as a mirror when the display device does not display an image.

### CROSS-REFERENCE TO RELATED APPLICATION

This application claims the benefit of Korean Patent Application No. 2009-9730, filed Feb. 6, 2009, in the Korean Intellectual Property Office, the disclosure of which is hereby incorporated herein by reference.

### BACKGROUND OF THE INVENTION

1. Field of the Invention

Aspects of the present invention relate to an organic light emitting diode (OLED) display device.

2. Description of the Related Art

In recent years, the developments of semiconductor fabrication technology and image processing technology have led to the rapid commercialization and increased usage of flat panel display devices (FPDs), which are lightweight and provide high-resolution images. The FPDs may include liquid crystal display devices (LCDs), plasma display panels (PDPs), vacuum fluorescent display devices (VFDs), and organic light emitting diode (OLED) display devices.

Among the above-described FPDs, the LCDs and OLED display devices are being broadly adopted for personal portable devices, such as portable phones, personal digital assistant (PDA), and portable computers, because they can be made thin and lightweight, and can produce high-resolution images. In particular, the LCDs and OLED display devices are widely used as outer and inner windows of dual-window portable phones.

An OLED display device is a self-emissive display device that electrically excites a fluorescent organic compound to emit light. In the OLED display device, an organic compound layer may be formed between a positive electrode (anode) and a negative electrode (cathode), and holes and electrons may be injected into the organic compound layer. The holes and electrons may recombine in the organic compound layer and generate light to display an image.

In order to meet various users' demands, electronic appliances are becoming increasingly multifunctional. As a result, research is being conducted toward developing multifunctional OLED display devices having not only a display function, but also other functions.

### SUMMARY OF THE INVENTION

Aspects of the present invention provide an organic light emitting diode (OLED) display device including a first substrate, OLEDs disposed on the first substrate, an encapsulation substrate that faces the first substrate, and reflective layers formed on the encapsulation substrate. The reflective layers are staggered with respect to the OLEDs, so that the display device can be used as a mirror when the display device does not display an image.

According to aspects of the present invention, the reflective layers may be disposed on a top surface or a bottom surface of the second substrate.

According to aspects of the present invention, the OLED display device may further include a thin film transistor (TFT) having a semiconductor layer. The TFT may be disposed between the first substrate and the OLEDs.

According to aspects of the present invention, the reflective layers may have a reflection rate of 90%, or higher.

According to aspects of the present invention, the reflective layers may each include at least one thin layer selected from the group consisting of a chrome (Cr)-based metal layer, an aluminum (Al)-based metal layer, a silver (Ag)-based metal layer, a tin (Sn)-based metal layer, a molybdenum (Mo)-based metal layer, an iron (Fe)-based metal layer, a platinum (Pt)-based metal layer, and a mercury (Hg)-based metal layer.

According to aspects of the present invention, the OLED display device may further include at least one moisture absorbent material.

According to aspects of the present invention, each of the OLEDs may include a pixel electrode, an organic emission layer (EML), and an opposing electrode.

According to aspects of the present invention, the OLED display device may further include an emission protection layer covering the OLEDs.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the exemplary embodiments, taken in conjunction with the accompanying drawings, of which:

FIG. 1 is a cross-sectional view of an organic light emitting diode (OLED) display device, according to an exemplary embodiment of the present invention; and

FIG. 2 is a cross-sectional view of a unit pixel of an active-matrix OLED.

### DETAILED DESCRIPTION OF THE EXEMPLARY EMBODIMENTS

Reference will now be made in detail to the exemplary embodiments of the present invention, examples of which are illustrated in the accompanying drawings, wherein like reference numerals refer to the like elements throughout. The exemplary embodiments are described below, in order to explain the aspects of the present invention, by referring to the figures.

Herein, when a first element is referred to as being formed or disposed “on” a second element, the first element can be disposed directly on the second element, or one or more other elements may be disposed therebetween. When a first element is referred to as being formed or disposed “directly on” a second element, no other elements are disposed therebetween.

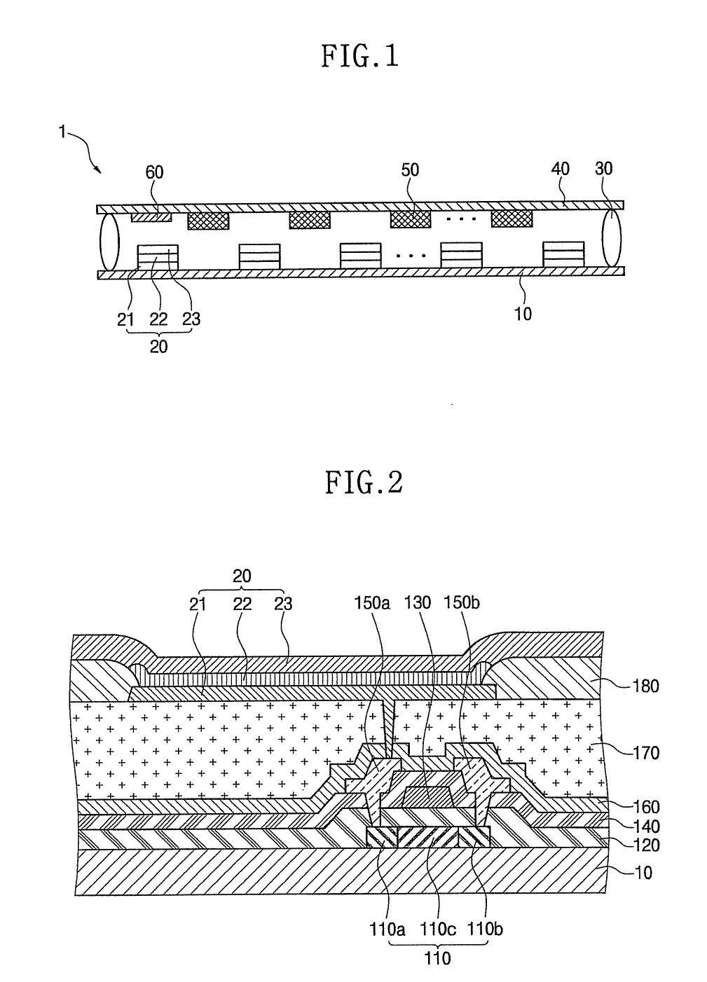

FIG. 1 is a cross-sectional view of an organic light emitting diode (OLED) display device 1, according to an exemplary embodiment of the present invention. Referring to FIG. 1, the OLED display device 1 includes a plurality of OLEDs 20 formed on a surface of a first substrate 10. Each of the OLEDs 20 includes a pixel electrode 21, an organic emission layer (EML) 22, and an opposing electrode 23.

Although not shown, a hole injection layer (HIL) and a hole transport layer (HTL) may be formed between the pixel electrode 21 and the organic EML 22, and an electron transport layer (ETL) and an electron injection layer (EIL) may be formed between the organic EML 22 and the opposing electrode 23. The first substrate 10 may be selected from the group consisting of a glass substrate, a plastic substrate, and a metal substrate.

A buffer layer (not shown) may be formed on the first substrate 10. The buffer layer may prevent the diffusion of moisture and/or impurities from the first substrate 10. The buffer layer may be formed of silicon oxide (SiO₂), or silicon nitride (SiNₓ), for example.

A sealant 30 may be coated between edges of the first substrate 10 and a second substrate 40, so as to encapsulate the OLEDs 20 and bond to the first substrate 10 to the second substrate 40. As a result, the first and second substrates 10 and 40 may be hermetically sealed by the sealant 30, so that the OLEDs 20 can be protected from moisture.

The sealant 30 may be an ultraviolet (UV)-curable material, such as an epoxy, or a heat curable material. Alternatively, the sealant 30 may contain spacers, such as polymer beads or silica particles.

The second substrate 40 includes a bottom surface that faces the first substrate 10 and an opposing top surface. Reflective layers 50 are formed on the bottom surface of second substrate 40. The reflective regions 50 are staggered with respect to the OLEDs 3. In other words, the reflective layers 50 do not directly face the OLEDs 3, and allow light from the OLEDs 3 to pass therebetween.

The reflective layers 50 may alternatively be formed on the top surface of the second substrate 40. In this case, however, the reflective layers 50 may be susceptible to scratches or damage. Thus, the reflective layers 50 are generally formed on the bottom surface of the second substrate 40.

The reflective layers 50 may be formed as a single reflective layer (not shown) that completely covers the bottom or top surface of the second substrate 40. In this case, the single reflective layer should have a predetermined transmission rate and a predetermined reflection rate. In particular, the predetermined transmission rate should be set to allow the OLED display device 1 to properly display an image, and the predetermined reflection rate should be set such that the single reflection layer operates as a mirror, when the OLED display device 1 does not display an image.

However, because the reflective layers 50 are staggered with respect to the OLEDs 3, the reflective layers 50 need not have the predetermined reflection and transmission rates, because the light from the OLEDs 20 can pass between the reflective layers and thereby display an image without passing through the reflective layers 50. Therefore, a wider variety of materials can be used for the reflective layers 50, without significantly degrading the luminous efficiency of the OLED display device 1. In particular, the reflective layers 50 may be formed of a chrome (Cr)-based metal layer, an aluminum (Al)-based metal layer, a silver (Ag)-based metal layer, a tin (Sn)-based metal layer, a molybdenum (Mo)-based metal layer, an iron (Fe)-based metal layer, a platinum (Pt)-based metal layer, a mercury (Hg)-based metal layer, or a combination thereof. Also, the reflective layers 50 may have a reflection rate of at least about 90% and a transmission rate below 10%.

The OLED display device 1 may further include a moisture absorbent material 60. The moisture absorbent material 60 may be selected from the group consisting of BaO, GaO, zeolite, CaO, or a metal oxide. Alternatively, the moisture absorbent material 60 may be a transparent moisture absorbent material, such as Polymer Nano Porous Layer (PNPL).

The moisture absorbent material 60 may be disposed between the first and second substrates 10 and 40. For example, the moisture absorbent material 60 may be formed on a top surface of the first substrate 1, or the bottom surface of the second substrate 40. The moisture absorbent material should be positioned so as not to degrade the luminous efficiency of the OLED display device 1.

The OLED display device 1 may further include an emission protection layer (not shown) covering the OLEDs 20, in order to protect the OLEDs 20 from air. The emission protection layer may be formed of one selected from the group consisting of SiNₓ, SiO₂, and Al₂O₃, to a thickness of from about 10 to 5000 Å. When the emission protection layer is formed to a thickness of less than about 10 Å, the protection effect of the emission protection layer may not be sufficient. When the emission protection layer is formed to a thickness of more than about 5000 Å, the luminous efficiency may be lowered, and processing time may be unnecessarily increased.

The present invention may be applied to an OLED display device including passive-matrix OLEDs (passive-matrix OLED display device) and to an OLED display device including active-matrix OLEDs (active-matrix OLED display device). An active-matrix OLED display device will be described with reference to FIG. 2, which is a cross-sectional view of a unit pixel of an active-matrix OLED. Referring to FIG. 2, the active-matrix OLED display device includes a TFT interposed between a first substrate 10 and an OLED 20.

A buffer layer (not shown) may be formed on the first substrate 10. The buffer layer may prevent diffusion of moisture and/or impurities from the first substrate 10. Thereafter, an amorphous silicon (a-Si) layer may be formed on the buffer layer and crystallized into a polycrystalline silicon (poly-Si) layer. The poly-Si layer may be patterned to form a semiconductor layer 110 having a predetermined pattern. During or after the formation of the a-Si layer, a dehydrogenation process may be performed to lower the hydrogen concentration thereof.

Thereafter, a gate insulating layer 120 may be formed on the first substrate 10 and the semiconductor layer 110, to protect underlying elements and electrically insulate the underlying elements from other elements that will be formed on the gate insulating layer 120. Afterwards, a metal layer, formed of aluminum (Al), an aluminum (Al) alloy, molybdenum (Mo), or a molybdenum (Mo) alloy, may be deposited on the gate insulating layer 120. The metal layer is patterned to form a gate electrode 130 corresponding to a region of the semiconductor layer 110.

Subsequently, N-type or P-type impurities may be implanted in the semiconductor layer 110, using the gate electrode 130 as a mask, thereby forming source and drain regions 110a and 110b in the semiconductor layer 110. In this case, the source and drain regions 110a and 110b flank a channel region 110c that is not doped with the impurities.

Thereafter, an interlayer insulating layer 140 is formed on the gate insulating layer 120 and the gate electrode 130. The interlayer insulating layer 140 protects and insulates the underlying elements from elements that will be formed on the interlayer insulating layer 140. The buffer layer, the gate insulating layer 120, and the interlayer insulating layer 140 may be formed of silicon oxide (SiO₂), silicon nitride (SiNₓ), or multiple layers thereof.

Contact holes are formed in the interlayer insulating layer 140 and the gate insulating layer 120, to expose the source and drain regions 110a and 110b. Source and drain electrodes 150a and 150b are formed on the interlayer insulating layer 140 and connected to the source and drain regions 110a and 110b, respectively, through the contact holes, thereby completing the TFT. The source and drain electrodes 150a and 150b may be formed of one selected from the group consisting of Al, an Al alloy, Mo, and an Mo alloy.

A TFT protection layer 160 is formed on the first substrate 10 and the TFT. The TFT protection layer 160 may be formed of SiO₂, SiNₓ, or multiple layers thereof.

A planarization layer 170 is then formed on the TFT protection layer 160. The planarization layer 170 may be an organic layer. The planarization layer 170 may be formed of one selected from the group consisting of acryl, benzocyclobutene (BCB), and polyimide.

The TFT protection layer 160 and the planarization layer 170 are etched, thereby forming a hole exposing one of the source and drain electrodes 150a and 150b. A pixel electrode 21 is formed on the planarization layer 170. The pixel electrode 21 is connected to the exposed source or drain electrode 150a and 150b. The pixel electrode 21 may be a transparent electrode formed of indium tin oxide (ITO) or indium zinc oxide (IZO).

A reflective layer (not shown) may be formed under the pixel electrode 21, to provide a top-emitting OLED. The reflective layer may be formed of one selected from the group consisting of platinum (Pt), gold (Au), iridium (Ir), chrome (Cr), magnesium (Mg), silver (Ag), aluminum (Al), and an alloy thereof. The reflective layer and the pixel electrode 21 may be stacked, in sequence.

A pixel defining layer 180, having an opening to expose the pixel electrode 21, is then formed. The pixel defining layer 180 may be formed of a material selected from the group consisting of benzocyclobutene (BCB), an acryl polymer, and a polyimide.

An organic EML 22 may be formed on the pixel electrode 21, and an opposing electrode 23 may be formed on the organic EML 22, thereby completing the formation of the OLED 20. Although not shown, an HIL and an HTL may be formed between the pixel electrode 21 and the organic EML 22, and an ETL and an EIL may be formed between the organic EML 22 and the opposing electrode 23.

Although only a TFT having a top-gate electrode is described above, the present invention is not limited thereto, and may be also applied to a TFT having a bottom-gate electrode. According to aspects of the present invention, reflective layers are formed on an encapsulation substrate. The reflection layers are staggered with respect to a plurality of OLEDs, so that an OLED display device can display images and operate as a mirror.

Although a few exemplary embodiments of the present invention have been shown and described, it would be appreciated by those skilled in the art that changes may be made in these exemplary embodiments without departing from the principles and spirit of the invention, the scope of which is defined in the claims and their equivalents.

What is claimed is:

1. An organic light emitting diode (OLED) display device comprising:
a first substrate;
OLEDs disposed on the first substrate;
a second substrate facing the first substrate, to encapsulate the OLEDs; and
reflective layers formed on the second substrate, which are separated so as not to directly face the OLEDs.

2. The OLED display device according to claim 1, wherein the reflective layers are disposed on a top surface of the second substrate, which faces away from the first substrate, or are disposed on an opposing bottom surface of the second substrate.

3. The OLED display device according to claim 1, further comprising thin film transistors (TFTs) disposed between the first substrate and the OLEDs.

4. The OLED display device according to claim 1, wherein the reflective layers have a reflection rate of at least about 90%.

5. The OLED display device according to claim 1, wherein the reflective layers each comprise one selected from the group consisting of a chrome (Cr)-based metal layer, an aluminum (Al)-based metal layer, a silver (Ag)-based metal layer, a tin (Sn)-based metal layer, a molybdenum (Mo)-based metal layer, an iron (Fe)-based metal layer, a platinum (Pt)-based metal layer, a mercury (Hg)-based metal layer, and a combination thereof.

6. The OLED display device according to claim 1, further comprising at least one moisture absorbent material disposed between the first and second substrates.

7. The OLED display device according to claim 1, wherein each of the OLEDs includes a pixel electrode, an organic emission layer, and an opposing electrode.

8. The OLED display device according to claim 1, further comprising an emission protection layer disposed on the OLEDs.

9. The OLED display device according to claim 8, wherein the thickness of the emission protection layer is from about 10 Å to 5000 Å.

10. The OLED display device according to claim 1, wherein the reflective layers are disposed such that light generated by the OLEDs passes between the reflective layers, to form an image.
